(19) United States
(12) Patent Application Publication
(10) Pub. No.: US 2026/0128577 A1
(43) Pub. Date: May 7, 2026

(54) RAISED FLOOR TILE ELECTRONIC EQUIPMENT TRAY

(71) Applicant: Hubbell Incorporated (Delaware), Shelton, CT (US)

(72) Inventors: Tim Ortel, Monkton, MD (US); Dennis Burrell, Cedar Park, TX (US)

(21) Appl. No.: 19/369,706

(22) Filed: Oct. 27, 2025

Related U.S. Application Data
(60) Provisional application No. 63/712,222, filed on Oct. 25, 2024.

(51) Int. Cl. H02G 3/12; E04F 15/024; H05K 9/00

(52) U.S. Cl. CPC H02G 3/12; E04F 15/02452; H05K 9/0049; E04F 2290/02

(57) ABSTRACT

A raised floor tile enclosure system that includes a pedestal, a bracket connected to the pedestal, and an equipment tray assembly supported by the bracket. The equipment tray assembly includes a bottom wall, at least one side wall that extends from the bottom wall and at least partially forms an interior volume, and a support plate movably positioned within the interior volume. The raised floor tile enclosure system further includes electronic equipment supported by the support plate and a floor tile coupled to the equipment tray that can enclose the interior volume. The support plate can move toward the bottom wall when the floor tile us coupled to the equipment tray. The electronic equipment can be received entirely within the interior volume when enclosed by the floor tile.

### CROSS-REFERENCE TO RELATED APPLICATION

This application claims the benefit to U.S. Provisional Application No. 63/712,222, filed Oct. 25, 2024, the entire contents of which is incorporated by reference in its entirety.

### FIELD

The present invention is generally directed to a means and method for installing an access point or other electronic gear under a raised floor tile.

### BACKGROUND

Access points used for WIFI coverage are typically mounted to ceilings or walls. In examples where raised floor tile systems are used, access points may be installed under the floor.

Raised floors typically have electronic equipment installed in enclosures, made of metal or plastic, that are attached to the pedestal legs, using clamps and tools and the clamps require adjusting to achieve the correct height on the legs. Existing enclosures are mounted to the underside of the concrete floor tile, using screws or adhesive. Plastic enclosures allow RF signals to pass through but allows interference from other nearby electronics to interfere with the signal being propagated by the access point. Metal enclosures prevent RF inference but also block the signal being propagated by the access point.

### SUMMARY

In some forms, there is an RF sealed tray with an open top to permit RF signal transmission.

In some forms, there is an RF tray that can be installed and/or uninstalled without tools.

In some forms, there is an adjustable equipment tray that permits a face of an access point to be flush with the bottom of the floor tile regardless of access point model.

In some forms, there is equipment tray assembly for supporting an electronic access point that includes a bottom wall, at least one side wall that extends from the bottom wall and at least partially forms an interior volume, a coil spring that extends from the bottom wall, and a support plate coupled to the coil spring and translatable toward the bottom wall against a spring bias of the coil spring.

In some forms, there is a raised floor tile enclosure system that includes a pedestal, a bracket connected to the pedestal, and an equipment tray assembly supported by the bracket. The equipment tray assembly includes a bottom wall, at least one side wall that extends from the bottom wall and at least partially forms an interior volume, and a support plate movably positioned within the interior volume. The raised floor tile enclosure system further includes electronic equipment supported by the support plate and a floor tile coupled to the equipment tray that can enclose the interior volume. The support plate can move toward the bottom wall when the floor tile us coupled to the equipment tray. The electronic equipment can be received entirely within the interior volume when enclosed by the floor tile.

In some forms, there is a raised floor tile enclosure system that includes a pedestal, a bracket connected to the pedestal, and an equipment tray assembly supported by the bracket. The equipment tray assembly includes a bottom wall, at least one side wall that extends from the bottom wall and at least partially forms an interior volume, a coil spring that extends from the bottom wall, and a support plate coupled to the coil spring and translatable toward the bottom wall against a spring bias of the coil spring. The raised floor tile enclosure system further includes a wireless access point supported by the support plate and a floor tile coupled to the equipment tray that can enclose the interior volume. Contact between the floor tile and the wireless access point can cause the support plate to move against the spring bias. The wireless access point can be received entirely within the interior volume when enclosed by the floor tile.

In some forms, there is a method of installing a raised floor tile enclosure system. A first bracket is connected to a first pedestal. A second bracket is connected to a second pedestal. A third bracket is connected a third pedestal. A fourth bracket is connected to a fourth pedestal. An equipment tray assembly is positioned on top of the first bracket, second bracket, third bracket, and fourth bracket. The equipment tray assembly includes a bottom wall, at least one side wall that extends from the bottom wall and at least partially forms an interior volume, a coil spring that extends from the bottom wall, and a support plate coupled to the coil spring and translatable toward the bottom wall against a spring bias of the coil spring. One of a first wireless access point having a first shape and a second wireless access point having a second shape that is different than the first shape is selected. The selected one of the first wireless access point and the second wireless access point is positioned on the support plate. A floor tile is connected to the equipment tray assembly to enclose the interior volume to cause the support plate to move against the spring bias. The selected one of the first wireless access point and the second wireless access point can be received entirely within the interior volume when enclosed by the floor tile.

The disclosure herein should become evident to a person of ordinary skill in the art given the following enabling description and drawings. The drawings are for illustration purposes only and are not drawn to scale unless otherwise indicated. The drawings are not intended to limit the scope of the disclosure. The following enabling disclosure is directed to one of ordinary skill in the art and presupposes that those aspects within the ability of the ordinary skilled artisan are understood and appreciated.

### BRIEF DESCRIPTION OF THE DRAWINGS

Various aspects and advantageous features of the present disclosure will become more apparent to those of ordinary skill when described in the detailed description of preferred examples and references to the accompanying drawings wherein:

FIG. 1 is a top perspective view of a raised floor tile equipment tray assembly embodying the present invention.

FIG. 2 is bottom perspective view of FIG. 1.

FIG. 3 is a top perspective view of a mockup of four pedestals of a raised floor tile system, showing the four corner brackets attached to the tile plates of the pedestals.

FIG. 4 is a top perspective view of the tray assembly resting on the four corner brackets shown in FIG. 3.

FIG. 5 is a side perspective view of FIG. 4 with the floor tile installed.

FIG. 6 is a perspective view of the corner bracket used to support the tray assembly in the raised floor tile system.

FIG. 7 is a top perspective view of the tray assembly.

FIG. 8 is a top perspective view of the tray assembly with the equipment plate installed.

FIG. 9 is a side cross-sectional view of FIG. 8

FIG. 10 is a side cross-sectional view of FIG. 8 with the access point attached to the equipment plate.

### DETAILED DESCRIPTION

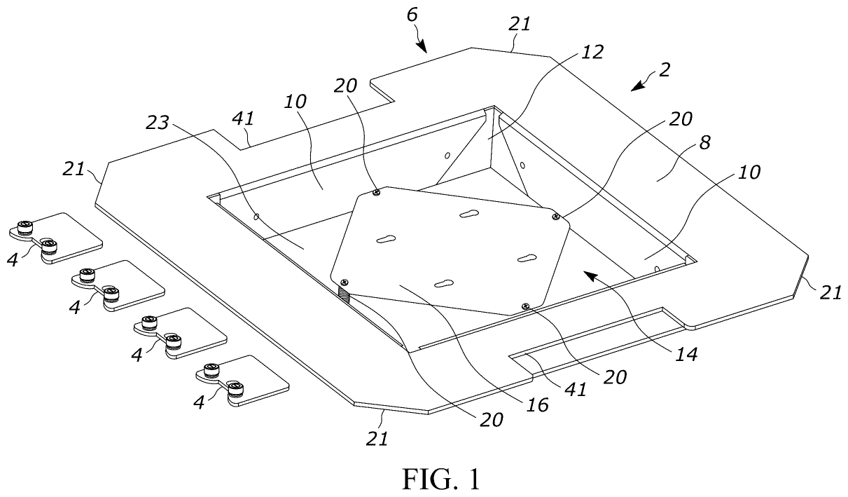

Referring to FIG. 1, a raised floor tile equipment tray assembly 2 embodying the present example is disclosed. The assembly 2 consists of four corner brackets 4 and a tray assembly 6 that holds the electronic equipment (not supplied), such as an access point. Other examples may include a different number of corner brackets 4 (e.g., a greater or lesser amount).

The tray assembly 6 includes a face plate 8 with downwardly extending walls 10 joined to the side walls 12 of a pan 14 by riveting or other standard means. The walls 10 advantageously overlap the side walls 12 of the pan 14 to help seal the pan.

An equipment plate 16 is attached to the bottom wall 18 of the pan 14. The equipment plate 16 is supported on springs 20 allow the plate 16 to move down as will be explained below.

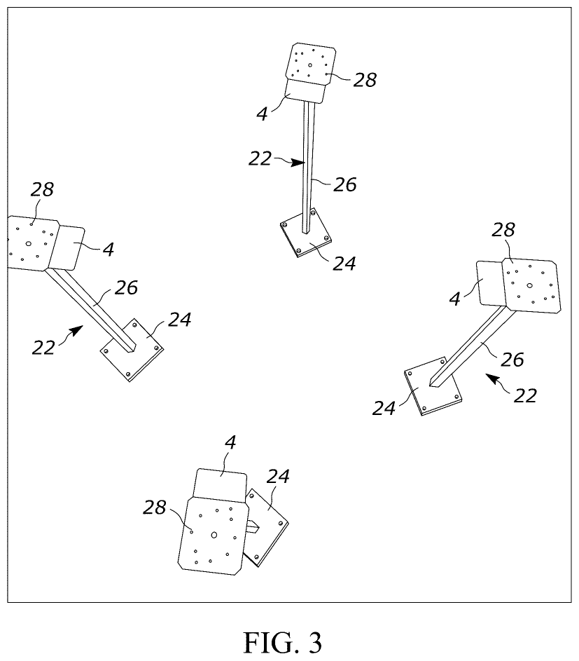

The face plate 8 may have truncated corners 21 for butting against the respective edges of the tile plates 28 (see e.g., FIG. 3). The face plate 8 may otherwise have a substantially rectangular shape.

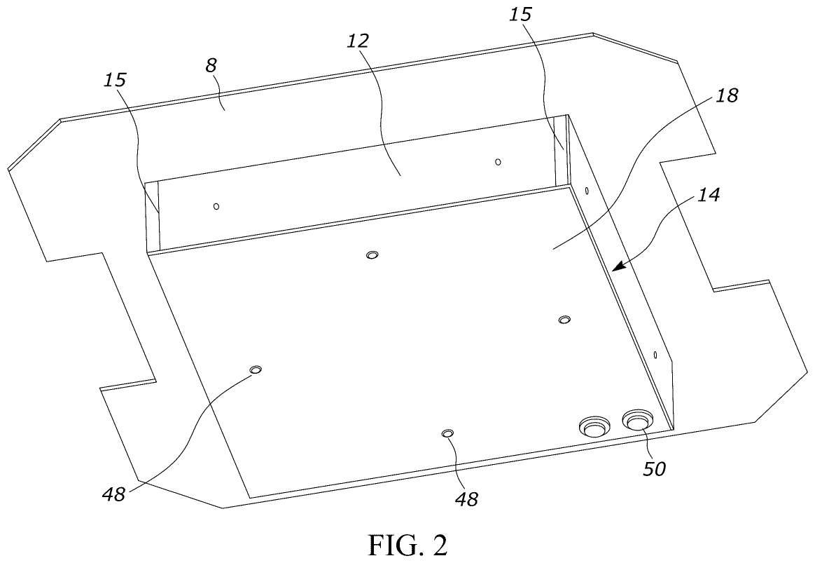

Referring to FIG. 2, the corners 15 of the pan 14 are bent over the side wall 12 to help seal the pan. Normal butt seams on bent sheet metal have generally open seams.

The tray assembly 6 advantageously provides an RF sealed tray on five sides and an open top 23 to allow RF signal transmission through the open top. The floor tile above the tray 6 is made of concrete through which RF can pass through. The tray assembly 6 is preferably made of metal or other materials to provide an RF sealed tray.

Referring to FIG. 3, the four corner brackets 4 are shown installed to the existing floor pedestals 22. The pedestals 22 are commercially available and part of a standard raised floor system. Each pedestal 22 generally includes a base plate 24, a leg 26 with its bottom end being attached to the base plate 10, and a tile plate 28 attached to the top end of the leg 26. The tile plates 28 support the floor tile. Each of the corner brackets 4 is attached to the respective undersides of the tile plates 28.

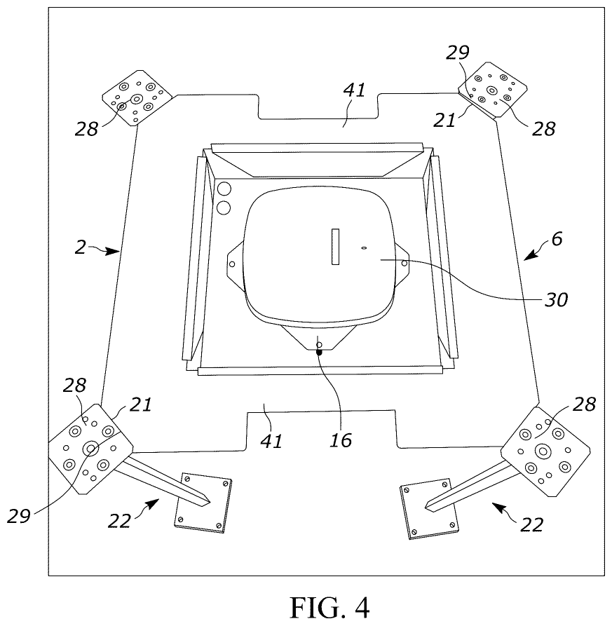

Referring to FIG. 4, the tray assembly 6 is shown installed on top of the corner brackets 4 (not visible). The tray assembly 6 simply rests on top of the corner brackets 4. The truncated corners 21 of the face plate 8 advantageously butt against the respective edges 29 of the respective tile plates 28 to minimize lateral movement and thus secure the tray assembly 6 in place. An electronic equipment 30, such as an access point, is attached to the equipment plate 16. The raised floor tile equipment tray assembly 2 advantageously allows the user to install/uninstall the tray assembly 6 without use of tools. The tray assembly 6 is simply lifted up since it is simply resting on the corner brackets 4. The tray assembly 6 is not directly attached to the legs 22 or to the underside of the concrete floor tile.

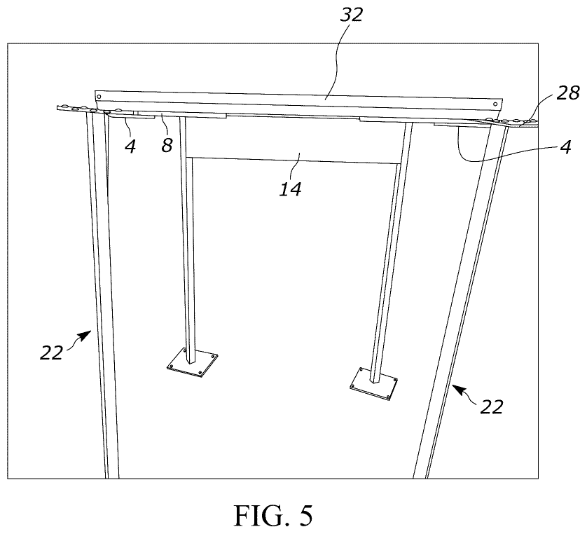

Referring to FIG. 5, the concrete floor tile 32 is shown installed on top of the tile plates 28 of the pedestals 22. The tray assembly 6 is simply supported by the corner brackets 4 via the face plate 8 without any attachment hardware. The tray assembly does not interfere with the installation of the floor tile 32 above. Installation of the floor tile equipment tray assembly 2 does not raise the level of the floor tile that it is being installed under, staying flush with the adjacent floor tiles to advantageously prevent creating a tripping hazard. The corner brackets 4 advantageously provides a consistent height of installation of the tray assembly 6 without any tools required. The tray assembly 6 is advantageously not directly attached to the pedestal legs, so that the existing wiring, plumbing or HVAC already attached to the pedestal legs do not have to be moved. The tray assembly 6 is also not attached to the floor tile 32, advantageously allowing for easy access to the access point 30.

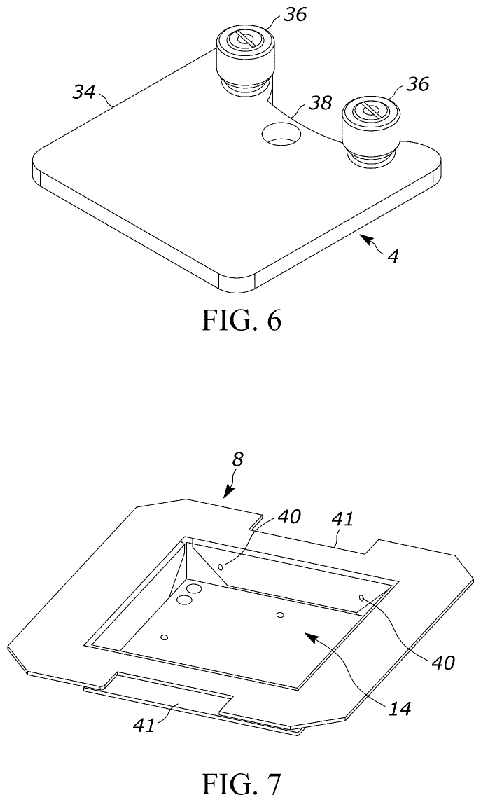

Referring to FIG. 6, the corner bracket 4 is shown, which is made up of an aluminum plate 34 and panel thumb screws 36 that are press fit into openings in the aluminum plate 34 to hold the screws in place. The illustrated example includes two thumb screws 36, although other examples may include a different number. The corner brackets 4 are fastened underneath the existing pedestal tile plates 28 by simply threading the panel screws 36 by hand into the existing threaded holes in the pedestal tile plates 28. A cutout 38 allows the bracket 4 to be positioned close to the leg 26 when lining up the screws 36 with the threaded openings in the tile plate 28. By fastening underneath the pedestal tile plates 28, the height of the floor tile that rests on the pedestal tile plates 28 is not affected. The top surface of the tile remains flush with the adjacent floor tiles.

Referring to FIG. 7, the tray 6 consists of the face plate 8 and the pan 14. The face plate 8 and the pan 14 are attached together by rivets 40 or other standard means. Rectangular cut outs 41 in face plate 8 serve as handles to allow for easy placement and removal of the tray assembly.

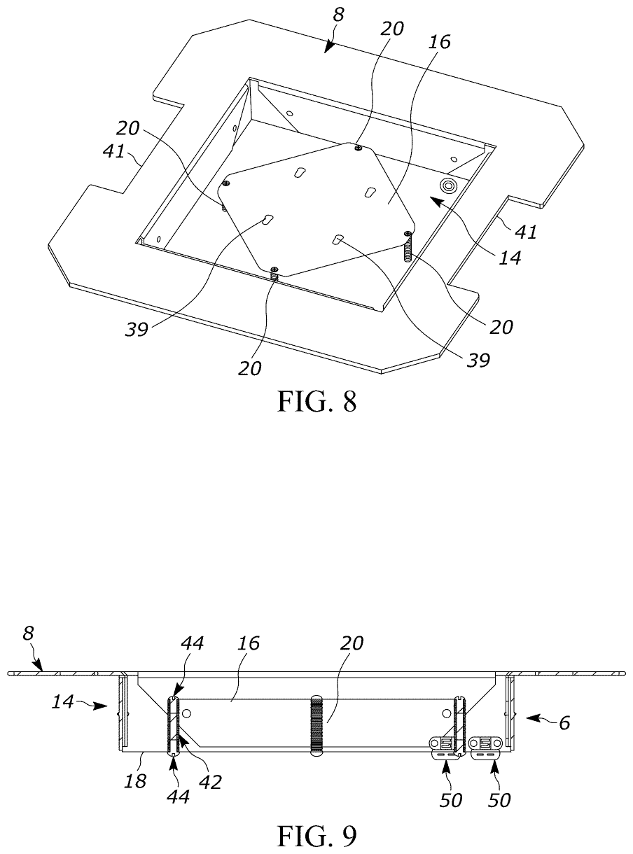

Referring to FIG. 8, the equipment plate 16 is shown installed in the pan 14. Springs 20 support the equipment plate 16 so it can float up and down in the pan 14. Openings 39 in the equipment plate 16 are provided for attaching the electronic equipment 30 to the equipment plate 16 with screws.

Referring to FIG. 9, the tray assembly 6 is shown. The equipment plate 16 rests on the four springs 20 so that the plate height with the electronic equipment installed is self-adjusting when the floor tile 32 is installed. This allows the face of the electronic equipment 30, in the case an access point, installed on the equipment plate 16 to rest against the bottom of the floor tile 32, advantageously improving RF signal propagation through the floor tile. The springs 20, preferably in helical coil form, are wound around respective cylindrical aluminum spacers 42. The springs 20 are free to move up and down around the spacers 42. Screws 44 attach the spacers 42 to the equipment plate 16 and the bottom wall 18 of the pan 14. The bottom wall 18 of the pan 14 has clearance holes 47 to allow the aluminum spacers 42 to protrude through the bottom wall 18 when the springs 20 are compressed when the floor tile is installed. Cable glands 50 allow wires that run under the floor system to enter the tray assembly 2 and power the electronic equipment, such as the access point 30. The springs 20 have larger diameters than the clearance holes 47 so that the springs 20 are always disposed between the bottom wall 18 and the equipment plate 16 as the springs 20 compress and the spacers 42 protrude through the clearance holes 47.

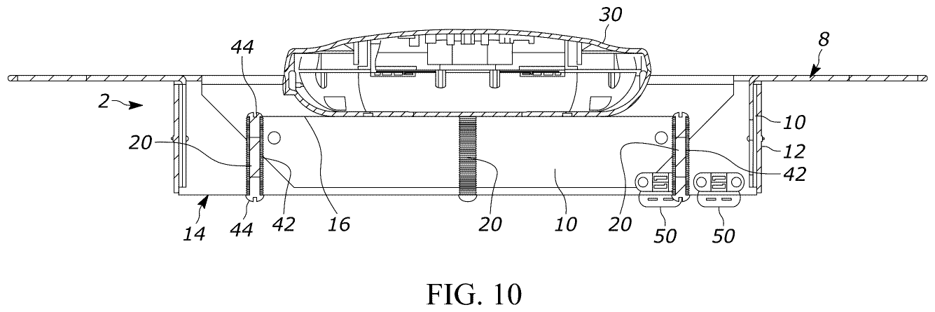

Referring to FIG. 10, the access point 30 (not supplied) is shown installed on the equipment tray assembly 2. The access point 30 is attached to the equipment plate 16. The tray assembly 6 advantageously provides protection to the access point 30 from interference from other nearby existing electronic equipment since the tray 6 is RF sealed on five sides and an open top 23 to allow RF signal transmission through the concrete floor tile 32 above.

When the floor tile 32 is installed, the springs 20 are compressed to allow the access point 30 move down. The adjustable equipment tray 2 advantageously allows the face of the access point 30 to be flush with the bottom of the floor tile 32 regardless of access point model used. The adjustable equipment plate 16 provided by the use of the springs 20 advantageously allows the tray assembly 6 to accommodate various models of the access points 30 with different housing thicknesses. The tray 2 advantageously stays clear of the pedestal legs 26 on which other infrastructure, such as cables, plumbing, HVAC, etc. are typically attached. Only the required floor tile needs to be removed to install the tray assembly 2. All adjacent tiles remain installed as the floor tile system is installed completely before electronic surveys are done to determine placement of electronics. The tray assembly 2 advantageously allows the existing floor tile 32 to be used without modification.

To install the tray assembly 2, the four corner brackets 4 are first attached to the underside of the existing pedestal tile plates 28 by hand tightening the panel thumb screws 36 attached to the corner brackets to the existing threaded holes in the tile plates 28.

Once all the four corner brackets are installed, power/RF cables are run through the bottom of the tray via the cable glands 50. Then the tray assembly 2 is simply rested onto the corner brackets without using any attachment hardware. The thickness of the face plate 8 matches the existing pedestal tile plate thickness so that when the floor tile 32 is installed, the top of the floor tile is flush with the adjacent floor tiles. The access point 30 (not supplied) is placed on the equipment plate 16 of the tray assembly and the power/RF cale is connected.

The concrete floor tile 32 is then placed on top of the tray assembly to rest on top of the existing pedestal tile plates 28. The weight of the tile 32 compresses the springs 20 under equipment plate 16, allowing the face of the access point 30 to be flush with the bottom of the floor tile 32, completing the installation.

By mounting the tray assembly 6 with the corner brackets 4 attached to the tile plates of the pedestals, existing equipment already attached to the pedestal legs, such electronic equipment in metal or plastic enclosures, wiring, plumbing, or HVAC, do not have to be moved, which can be complicated since the locations of these existing equipment are random and cannot be moved.

The floor tile tray assembly 6 just rests on top of the corner brackets 4, advantageously allowing for quick installation. The thickness of the face plate 8 matches the existing pedestal tile plate thickness to provide an “RF” seal from outside interference from nearby electronics. When fully installed the face plate is flush with the bottom of the floor tile. This allows the top of the floor tile to be flush with adjacent tiles to prevent tripping hazards.

While this disclosure has been described as having preferred design, it is understood that it is capable of further modifications, uses and/or adaptations following in general the principle of the invention and including such departures from the present disclosure as come within known or customary practice in the art to which the invention pertains, and as may be applied to the essential features set forth, and fall within the scope of the invention or the limits of the appended claims.

One of ordinary skill will appreciate that the exact dimensions and materials are not critical to the disclosure and all suitable variations should be deemed to be within the scope of the disclosure if deemed suitable for carrying out the objects of the disclosure.

One of ordinary skill in the art will also readily appreciate that it is well within the ability of the ordinary skilled artisan to modify one of more of the constituent parts for carrying out the various examples of the disclosure. Once armed with the present specification, routine experimentation is all that is needed to determine adjustments and modifications that will carry out the present disclosure.

The above examples are for illustrative purposes and are not intended to limit the scope of the disclosure or the adaptation of the features described herein. Those skilled in the art will also appreciate that various adaptations and modifications of the above-described preferred examples can be configured without departing from the scope and spirit of the disclosure. Therefore, it is to be understood that, within the scope of the appended claims, the disclosure may be practiced other than as specifically described.

1. A raised floor tile enclosure system comprising:
a pedestal;
a bracket connected to the pedestal;
an equipment tray assembly supported by the bracket and including,
a bottom wall,
at least one side wall extending from the bottom wall and at least partially forming an interior volume, and
a support plate movably positioned within the interior volume;
electronic equipment supported by the support plate; and
a floor tile coupled to the equipment tray and configured to enclose the interior volume;
wherein the support plate is configured to move toward the bottom wall when the floor tile us coupled to the equipment tray; and
wherein the electronic equipment is configured to be received entirely within the interior volume when enclosed by the floor tile.

2. The raised floor tile enclosure system of claim 1, wherein the bottom wall and the at least one side wall are constructed from a first material configured to block transmission of RF waves, and where the floor tile is constructed from a second material configured to allow for the transmission of RF waves.

3. The raised floor tile enclosure system of claim 2, wherein the first material is a metal and the second material is concrete.

4. The raised floor tile enclosure system of claim 1, wherein the bracket includes a body and a thumb screw press fit into the body, and wherein the thumb screw is configured to connect the bracket to the pedestal.

5. The raised floor tile enclosure system of claim 1, wherein the equipment tray assembly further includes a faceplate coupled to the at least one side wall, and wherein the floor tile is configured to be coupled to the faceplate.

6. The raised floor tile enclosure system of claim 5, wherein the faceplate includes an outer perimeter formed outside of the interior volume, and wherein a cutout is disposed inward of the outer perimeter.

7. The raised floor tile enclosure system of claim 1, wherein a biasing member is coupled between the support plate and the bottom wall, and wherein the floor tile is configured to compress the biasing member and cause the support plate to move toward the bottom wall.

8. The raised floor tile enclosure system of claim 7, wherein a spacer is coupled to the bottom wall, and wherein the biasing member is a coil spring that is positioned against an outer surface of the spacer.

9. The raised floor tile enclosure system of claim 1, wherein a cable gland is formed through the bottom wall and configured to permit electrical cables to pass into the interior volume.

10. A raised floor tile enclosure system comprising:
a pedestal;
a bracket connected to the pedestal;
an equipment tray assembly supported by the bracket and including,
a bottom wall,
at least one side wall extending from the bottom wall and at least partially forming an interior volume,
a coil spring extending from the bottom wall, and
a support plate coupled to the coil spring and translatable toward the bottom wall against a spring bias of the coil spring;
a wireless access point supported by the support plate; and
a floor tile coupled to the equipment tray to enclose the interior volume;
wherein contact between the floor tile and the wireless access point is configured to cause the support plate to move against the spring bias; and
wherein the wireless access point is configured to be received entirely within the interior volume when enclosed by the floor tile.

11. The raised floor tile enclosure system of claim 10, wherein the bottom wall and the at least one side wall are constructed from a first material configured to block transmission of RF waves, and where the floor tile is constructed from a second material configured to allow for the transmission of RF waves, and wherein the first material is a metal and the second material is concrete.

12. The raised floor tile enclosure system of claim 10, wherein the bracket includes a body and a thumb screw press fit into the body, and wherein the thumb screw is configured to connect the bracket to the pedestal.

13. The raised floor tile enclosure system of claim 10, wherein the equipment tray assembly further includes a faceplate coupled to the at least one side wall, and wherein the floor tile is configured to be coupled to the faceplate.

14. The raised floor tile enclosure system of claim 13, wherein the faceplate includes an outer perimeter formed outside of the interior volume, and wherein a cutout is disposed inward of the outer perimeter.

15. The raised floor tile enclosure system of claim 10, wherein a biasing member is coupled between the support plate and the bottom wall, and wherein the floor tile is configured to compress the biasing member and cause the support plate to move toward the bottom wall.

16. The raised floor tile enclosure system of claim 15, wherein a spacer is coupled to the bottom wall, and wherein the biasing member is a coil spring that is positioned against an outer surface of the spacer.

17. The raised floor tile enclosure system of claim 10, wherein a cable gland is formed through the bottom wall and configured to permit electrical cables to pass into the interior volume.

18. A method of installing a raised floor tile enclosure system comprising:
connecting a first bracket to a first pedestal;
connecting a second bracket to a second pedestal;
connecting a third bracket to a third pedestal;
connecting a fourth bracket to a fourth pedestal;
positioning an equipment tray assembly on top of the first bracket, second bracket, third bracket, and fourth bracket, wherein the equipment tray assembly includes,
a bottom wall,
at least one side wall extending from the bottom wall and at least partially forming an interior volume,
a coil spring extending from the bottom wall, and
a support plate coupled to the coil spring and translatable toward the bottom wall against a spring bias of the coil spring;
selecting between a first wireless access point having a first shape and a second wireless access point having a second shape that is different than the first shape;
positioning the selected one of the first wireless access point and the second wireless access point on the support plate; and
connecting a floor tile to the equipment tray assembly to enclose the interior volume to cause the support plate to move against the spring bias;
wherein the selected one of the first wireless access point and the second wireless access point is configured to be received entirely within the interior volume when enclosed by the floor tile.

19. The method of claim 18, further comprising,
removing the floor tile from the equipment tray;
replacing the selected one of the first wireless access point and the second wireless access point with the other of the first wireless access point and the second wireless access point; and
reconnecting the floor tile to the equipment tray assembly.

20. The method of claim 18, wherein positioning an equipment tray assembly on top of the first bracket, second bracket, third bracket, and fourth bracket includes placing the equipment tray assembly on top of the first bracket, second bracket, third bracket, and fourth bracket without use of additional fasteners or tools.

21-26. (canceled)
